(19) United States
(12) Patent Application Publication
(10) Pub. No.: US 2022/0375970 A1
(43) Pub. Date: Nov. 24, 2022

(54) SEMICONDUCTOR ARRANGEMENT AND METHOD OF MAKING

(71) Applicant: TAIWAN SEMICONDUCTOR MANUFACTURING COMPANY LIMITED, Hsin-Chu (TW)

(72) Inventors: Chia Jung HSU, Tainan City (TW); Chia-Yu WEI, Tainan City (TW); Kuo-Cheng LEE, Tainan City (TW); Chen YING-HAO, Tainan City (TW)

(21) Appl. No.: 17/874,366

(22) Filed: Jul. 27, 2022

Related U.S. Application Data
(62) Division of application No. 16/880,038, filed on May 21, 2020.

(51) Int. Cl. H01L 27/146

(52) U.S. Cl. CPC H01L 27/1463; H01L 27/1465; H01L 27/14687

(57) ABSTRACT

A semiconductor arrangement is provided. The semiconductor arrangement includes a first component in a substrate. The semiconductor arrangement includes a gap fill layer. A first portion of the gap fill layer overlies the first component. The first portion of the gap fill layer has a tapered sidewall. A first portion of the substrate separates the first portion of the gap fill layer from the first component.

### RELATED APPLICATIONS

This application is a divisional of and claims priority to U.S. patent application Ser. No. 16/880,038, titled “SEMICONDUCTOR ARRANGEMENT AND METHOD OF MAKING” and filed on May 21, 2020, which is incorporated herein by reference.

### BACKGROUND

Semiconductor arrangements are used in a multitude of electronic devices, such as mobile phones, laptops, desktops, tablets, watches, gaming systems, and various other industrial, commercial, and consumer electronics. Semiconductor arrangements generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15 illustrate cross-sectional views of a semiconductor arrangement at various stages of fabrication, in accordance with some embodiments.

FIG. 16 illustrates a cross-sectional view of a semiconductor arrangement, in accordance with some embodiments.

FIG. 17 illustrates a cross-sectional view of a semiconductor arrangement, in accordance with some embodiments.

FIG. 18 illustrates a cross-sectional view of a semiconductor arrangement, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

Some embodiments relate to a semiconductor arrangement. In accordance with some embodiments, the semiconductor arrangement comprises a first component, such as a first photodiode, in a substrate, such as a semiconductor wafer. The semiconductor arrangement comprises a gap fill layer. A first portion of the gap fill layer overlies the first component. In some embodiments, the first portion of the gap fill layer has a tapered sidewall. The first portion of the gap fill layer having the tapered sidewall overlying the first component has a higher absorption of radiation as compared to a gap fill layer not having a tapered sidewall, and thereby directs more radiation to the first component. In some embodiments, the first portion of the gap fill layer is a high absorption (HA) structure. A gap fill layer not having a tapered sidewall is not a HA structure and scatters or reflects more radiation away from the first component as compared to the first portion of the gap fill layer having the tapered sidewall.

In some embodiments, a second portion of the gap fill layer is laterally offset from the first component and a second component in the substrate so as to be between the first component and the second component. The second portion of the gap fill layer corresponds to a deep trench isolation (DTI) feature. In some embodiments, the semiconductor arrangement is generally formed in the backside of the substrate such that the second portion of the gap fill layer corresponds to a backside DTI (BDTI) feature. In some embodiments, the second component comprises a second photodiode. The second portion of the gap fill layer inhibits radiation directed toward the first component, such as by the tapered first portion of the gap fill layer, from travelling to the second component, and thereby at least one of inhibits cross talk between the first component and the second component or enhances a modulation transfer function (MTF), where a higher MTF provides for improved resolution.

In some embodiments, at least one of the first component, the second component, or other components in the substrate comprise a material that is relatively highly absorptive to near infrared (NIR) wavelengths. At least one of the first component, the second component, or other components in the substrate comprise at least one of germanium or other suitable material. Implementing at least one of the first portion of the gap fill layer having the tapered sidewall, the second portion of the gap fill layer that is laterally offset from the first component in the substrate, or the first component comprising the highly absorptive material increases quantum efficiency (QE) to about 94%, such as for NIR wavelengths, which is higher than the QE of semiconductor arrangements not having at least one of the tapered first portion of the gap fill layer, the laterally offset second portion of the gap fill layer, or the highly absorptive first component. In some embodiments, the semiconductor arrangement operates as a sensor, such as at least one of an image sensor, a proximity sensor, or a different type of sensor. Given the increased QE, the semiconductor arrangement operates more efficiently than other sensors, such as requiring less power, being more effective in relatively low light situation, providing a higher resolution, etc.

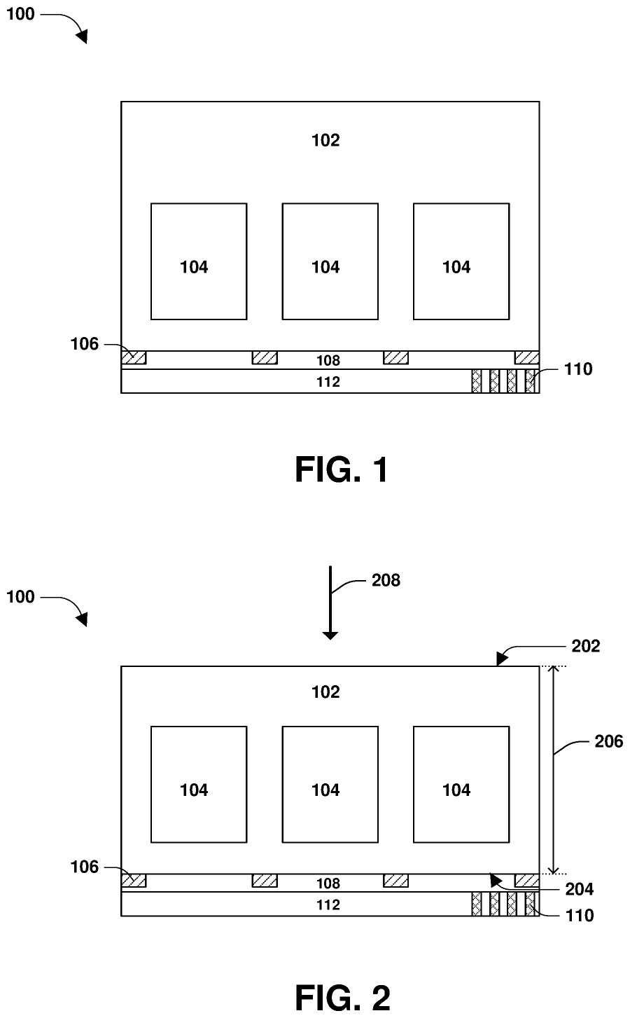

FIGS. 1-15 are cross-sectional views of a semiconductor arrangement 100, in accordance with some embodiments. In some embodiments, a sensor is implemented via the semiconductor arrangement 100. The sensor comprises at least one of an image sensor, a proximity sensor, a time of flight (ToF) sensor, an indirect ToF (iToF) sensor, a backside illumination (BSI) sensor, a complementary metal-oxide-semiconductor (CMOS) image sensor, a backside CMOS image sensor, or another type of sensor. Other structures and configurations of the semiconductor arrangement 100 and the sensor are within the scope of the present disclosure.

FIG. 1 illustrates the semiconductor arrangement 100 according to some embodiments. The semiconductor arrangement 100 comprises at least one of a first dielectric layer 112, a second dielectric layer 108, or a substrate 102. The first dielectric layer 112 comprises at least one of a low-k dielectric material or other suitable material. As used herein, the term “low-k dielectric material” refers to a material having a dielectric constant, k, lower than about 3.9. Some low-k dielectric materials have a dielectric constant lower than about 3.5 and some low-k dielectric materials have a dielectric constant lower than about 2.5.

One or more low-resistance structures 110 are disposed in the first dielectric layer 112, according to some embodiments. The one or more low-resistance structures 110 comprise a conductive material, such as at least one of a metal material or other suitable material. In some embodiments, the one or more low-resistance structures 110 provide interconnections, such as wiring, between at least one of various doped features, circuitry, input/output, etc. of the semiconductor arrangement 100. Other structures and configurations of the first dielectric layer 112 and the one or more low-resistance structures 110 are within the scope of the present disclosure.

The second dielectric layer 108 is formed over the first dielectric layer 112, according to some embodiments. In some embodiments, the second dielectric layer 108 is in direct contact with a top surface of the first dielectric layer 112. The second dielectric layer 108 comprises at least one of oxide or other suitable material. In some embodiments, the second dielectric layer 108 comprises un-doped silicate glass (USG) oxide. Other structures and configurations of the second dielectric layer 108 are within the scope of the present disclosure. In some embodiments, one or more structures 106 are disposed in the second dielectric layer 108. The one or more structures 106 comprise polysilicon or other suitable material. Other structures and configurations of the second dielectric layer 108 and the one or more structures 106 are within the scope of the present disclosure.

The substrate 102 is formed over the second dielectric layer 108, according to some embodiments. In some embodiments, the substrate 102 is in direct contact with a top surface of the second dielectric layer 108. The substrate 102 comprises at least one of an epitaxial layer, a silicon-on-insulator (SOI) structure, a wafer, or a die formed from a wafer. The substrate 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GalnAs, GaInP, GalnAsP or other suitable material. According to some embodiments, the substrate 102 comprises monocrystalline silicon, crystalline silicon with a <100>crystallographic orientation, crystalline silicon with a <110>crystallographic orientation or other suitable material. In some embodiments, the substrate 102 comprises at least one doped region. Other structures and configurations of the substrate 102 are within the scope of the present disclosure.

The substrate 102 comprises components 104, according to some embodiments. The components 104 are formed within the substrate 102, such as by doping the substrate 102. Other processes and techniques for forming the components 104 are within the scope of the present disclosure. In some embodiments, the components 104 comprise photodiodes. Other structures and configurations of the components 104 are within the scope of the present disclosure. The components 104 comprise at least one of pinned layer photodiodes, phototransistors, photogates, reset transistors, source follower transistors, transfer transistors, or a different type of component. In some embodiments, the components 104 vary from one another to have at least one of different junction depths, thicknesses, widths, material compositions, etc. In some embodiments, the components 104 do not vary from one another to have at least one of different junction depths, thicknesses, widths, material compositions, etc. Even though three components 104 are depicted, any number of components 104 are contemplated. In some embodiments, at least some of the components 104 comprise at least one of sources or drains of one or more transistors, such as at least one of a field-effect transistor (FET), a metal-oxide-semiconductor FET (MOSFET), a metal-insulator-semiconductor FET (MISFET), a metal-semiconductor FET (MESFET), an insulated-gate FET (IGFET), an insulated-gate bipolar transistor (IGBT), a high-electron mobility transistor (HEMT), a heterostructure FET (HFET), a modulation-doped FET (MODFET), or a different type of transistor. According to some embodiments, at least some of the components 104 are connected to at least one of sources or drains of one or more transistors, such as at least one of a FET, a MOSFET, a MESFET, an IGFET, an IGBT, an HEMT, an HFET, a MODFET, or a different type of transistor. In some embodiments, the one or more structures 106 are configured to facilitate at least one of providing voltages to the components 104 or driving the components 104. Other structures and configurations of the components 104 and the one or more structures 106 are within the scope of the present disclosure.

At least some of the components 104 comprise a material having an energy bandgap less than 1.6 electronvolts, according to some embodiments. Other materials and energy bandgaps of the components 104 are within the scope of the present disclosure. In some embodiments, at least some of the components 104 comprise a material having an energy bandgap that is less than an energy bandgap of silicon. Other materials and energy bandgaps of the components 104 are within the scope of the present disclosure. At least some of the components 104 comprise at least one of germanium, InAs, InSb, GaSb, GaAs, InP, or other suitable material. In some embodiments, at least some of the components 104 comprise a material that is relatively highly absorptive to NIR wavelengths, such as radiation with a wavelength between about 700 nanometers and about 2500 nanometers. Other materials of the components 104 and other wavelengths of radiation to which material of the components 104 is relatively highly absorptive are within the scope of the present disclosure.

FIG. 2 illustrates a reduced thickness of the substrate 102, according to some embodiments. A portion of the substrate 102 is removed, such as by at least one of chemical mechanical planarization (CMP), etching, or other suitable techniques, to reduce the thickness of the substrate 102. According to some embodiments, after removing the portion of the substrate 102, the substrate 102 has a thickness 206 between about 25,000 angstroms and about 60,000 angstroms. Other values of the thickness 206 are within the scope of the present disclosure. Other processes and techniques for forming the substrate 102 having the thickness 206 are within the scope of the present disclosure.

The substrate 102 has a first side 202 and a second side 204. In some embodiments, the substrate 102 is inverted such that the first side 202 corresponds to a back side of the substrate 102 and the second side 204 corresponds to a front side of the substrate 102. Other structures and configurations of the substrate 102 are within the scope of the present disclosure. In some embodiments, the components 104 are configured to sense radiation, such as incident light, which is projected towards the substrate 102 from the first side 202. Radiation entering the substrate 102 through the first side 202 is detected by one or more components 104. In some embodiments, radiation travels in a direction 208 to enter the substrate 102 and be detected by the components 104. Other structures and configurations of the substrate 102 and the components 104 are within the scope of the present disclosure.

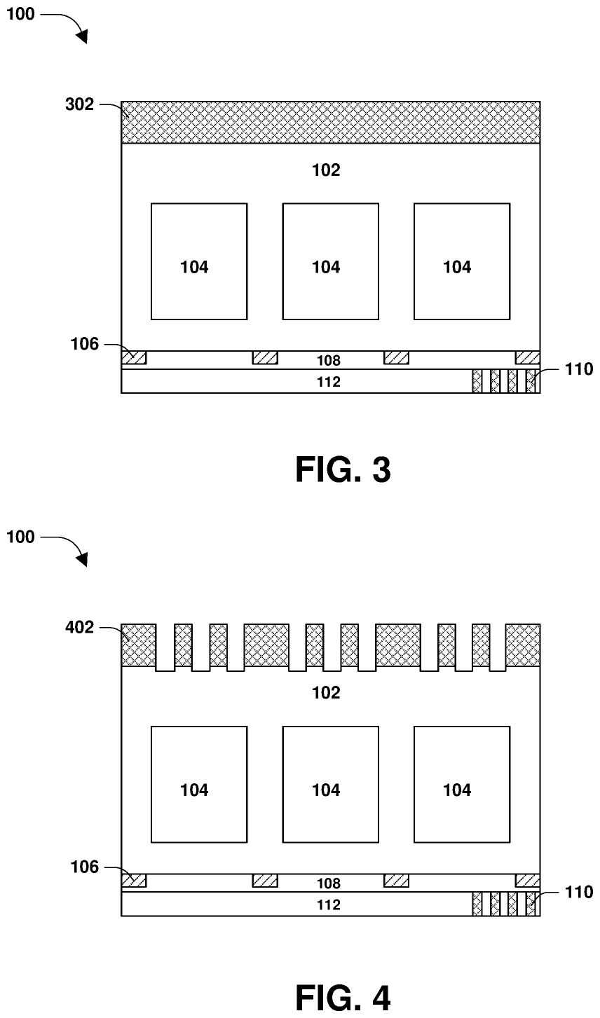

FIG. 3 illustrates a mask layer 302 formed over the substrate 102, according to some embodiments. In some embodiments, the mask layer 302 is in direct contact with a top surface of the substrate 102. In some embodiments, the mask layer 302 is a hard mask layer. The mask layer 302 comprises at least one of oxide, nitride, a metal, or other suitable material. The mask layer 302 is formed by at least one of physical vapor deposition (PVD), sputtering, chemical vapor deposition (CVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

FIG. 4 illustrates a patterned mask layer 402 formed over the substrate 102, according to some embodiments. The mask layer 302 is patterned to form the patterned mask layer 402. According to some embodiments, the mask layer 302 is patterned to form the patterned mask layer 402 using a photoresist (not shown). The photoresist is formed over the mask layer 302. The photoresist is formed by at least one of PVD, sputtering, CVD, LPCVD, ALCVD, UHVCVD, RPCVD, ALD, MBE, LPE, spin on, growth, or other suitable techniques. The photoresist comprises a light-sensitive material, where properties, such as solubility, of the photoresist are affected by light. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer, such as using at least one of hydrogen fluoride (HF), diluted HF, a chlorine compound such as hydrogen chloride (HCl₂), hydrogen sulfide (H₂S) or other suitable material. Other processes and techniques for forming the patterned mask layer 402 are within the scope of the present disclosure.

An etching process used to remove portions of the mask layer 302 to expose portions of the substrate 102 and form the patterned mask layer 402 is at least one of a dry etching process, a wet etching process, an anisotropic etching process, an isotropic etching process or other suitable etching process. The etching process uses at least one of HF, diluted HF, a chlorine compound such as HCl₂, H₂S, or other suitable material. In some embodiments, the etching process performed to remove portions of the mask layer 302 and form the patterned mask layer 402 also removes at least some of the substrate 102, such as portions of the substrate 102 underlying openings in the patterned mask layer 402. Other processes and techniques for removing portions of the mask layer 302 and forming the patterned mask layer 402 are within the scope of the present disclosure.

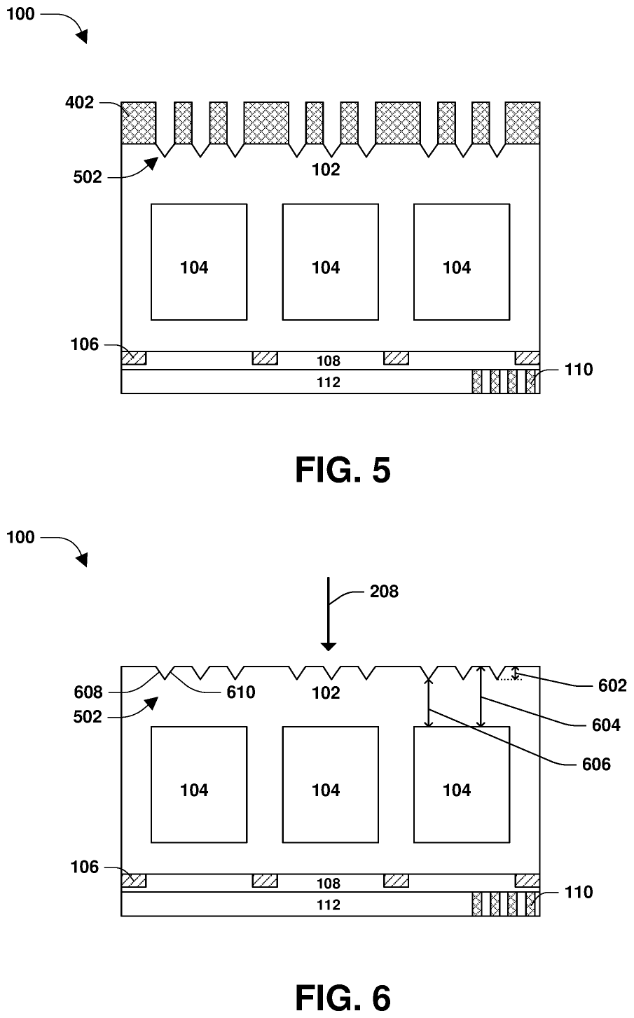

FIG. 5 illustrates use of the patterned mask layer 402 to form recesses 502 in the substrate 102, according to some embodiments. In some embodiments, an etching process is performed to form the recesses 502, where openings in the patterned mask layer 402 allow one or more etchants applied during the etching process to remove portions of the substrate 102 while the patterned mask layer 402 protects or shields portions of the substrate 102 that are covered by the patterned mask layer 402. The etching process is at least one of a dry etching process, a wet etching process, an anisotropic etching process, an isotropic etching process or other suitable etching process. The etching process uses at least one of HF, diluted HF, a chlorine compound such as HCl₂, H₂S or other suitable material.

In some embodiments, the recesses 502 comprise one or more recesses overlying a component 104. Even though three recesses 502 over a component 104 are depicted, any number of recesses 502 are contemplated. In some embodiments, given that a recess 502 is defined in the top surface of the substrate 102, a portion of the substrate 102 separates the recess 502 from the component 104. Other processes and techniques for forming the recesses 502 are within the scope of the present disclosure.

FIG. 6 illustrates removal of the patterned mask layer 402, according to some embodiments. The patterned mask layer 402 is removed after the recesses 502 are formed. In some embodiments, the patterned mask layer 402 is removed by at least one of CMP or etching. The etching process is at least one of a dry etching process, a wet etching process, an anisotropic etching process, an isotropic etching process, or other suitable etching process. The etching process uses at least one of HF, diluted HF, a chlorine compound such as HCl₂, H₂S, or other suitable material. Other processes and techniques for removing the patterned mask layer 402 are within the scope of the present disclosure.

A portion of the substrate 102 has at least one of a first tapered sidewall 608 or a second tapered sidewall 610 defining a recess 502. In some embodiments, the recess 502 has the first tapered sidewall 608 and the second tapered sidewall 610. At least one of the first tapered sidewall 608 has a first slope, such as a negative slope, or the second tapered sidewall 610 has a second slope, such as a positive slope. In some embodiments, the second slope is opposite in polarity relative to the first slope. In some embodiments, a recess 502 has a triangular shape. In some embodiments, a cross-sectional area of a recess 502 decreases along the direction 208. A width of an uppermost portion of a recess 502 is greater than a width of a lowermost portion of the recess 502. Other structures and configurations of the recesses 502 are within the scope of the present disclosure.

In some embodiments, the etching process performed to form the recesses 502 is performed such that the substrate 102 has tapered sidewalls defining the recesses 502, such as the first tapered sidewall 608 and the second tapered sidewall 610. One or more etchants used to perform the etching process are designed or selected to form the tapered sidewalls in the substrate 102 defining the recesses 502. According to some embodiments, the substrate 102 having a specific crystallographic orientation, such as crystalline silicon with at least one of a <100>crystallographic orientation or a <110>crystallographic orientation, enables the etching process to form the tapered sidewalls in the substrate 102 defining the recesses 502. Other processes and techniques for forming the sidewalls defining the recesses 502 are within the scope of the present disclosure.

In some embodiments, a distance 602 between a lowermost portion of a recess 502 and at least one of an uppermost portion of the recess 502 or the top surface of the substrate 102 is between about 500 angstroms and about 10,000 angstroms. Other values of the distance 602 are within the scope of the present disclosure. The distance 602 corresponds to a depth of a recess 502. In some embodiments, a distance 604 between the top surface of the substrate 102 and a top surface of a component 104 is between about 5,500 angstroms and about 30,000 angstroms. Other values of the distance 604 are within the scope of the present disclosure. In some embodiments, a distance 606 between a lowermost portion of a recess 502 and a top surface of a component 104 is between about 5,000 angstroms and about 20,000 angstroms. Other values of the distance 606 are within the scope of the present disclosure.

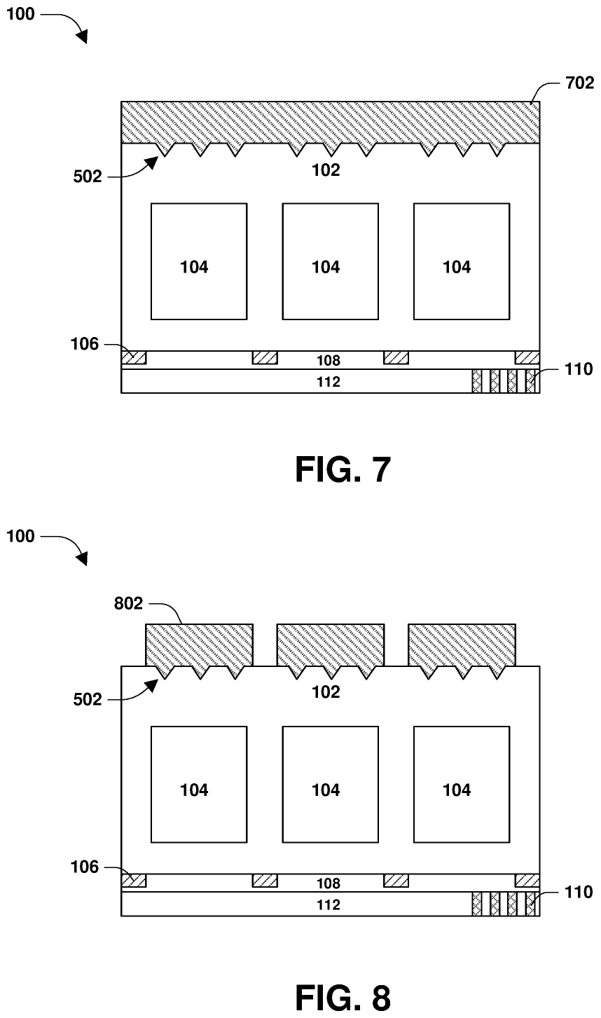

FIG. 7 illustrates a photoresist 702 formed over the substrate 102, according to some embodiments. In some embodiments, the photoresist 702 is in direct contact with the top surface of the substrate 102. In some embodiments, the photoresist 702 is in the recesses 502 of the substrate 102. The photoresist 702 is formed by at least one of PVD, sputtering, CVD, LPCVD, ALCVD, UHVCVD, RPCVD, ALD, MBE, LPE, spin on, growth, or other suitable techniques. The photoresist 702 comprises a light-sensitive material, where properties, such as solubility, of the photoresist 702 are affected by light. The photoresist 702 is a negative photoresist or a positive photoresist.

FIG. 8 illustrates a patterned photoresist 802 formed from the photoresist 702, according to some embodiments. The patterned photoresist 802 has openings exposing portions of the substrate 102. In some embodiments, the openings in the patterned photoresist 802 are between the components 104, such that the openings do not overlie or are laterally offset from the components 104. In some embodiments, an opening in the patterned photoresist 802 is between two adjacent components 104, such that the opening overlies a portion of the substrate 102 between a first component 104 and a second component 104. According to some embodiments, an opening in the patterned photoresist 802 overlies a portion of a component 104.

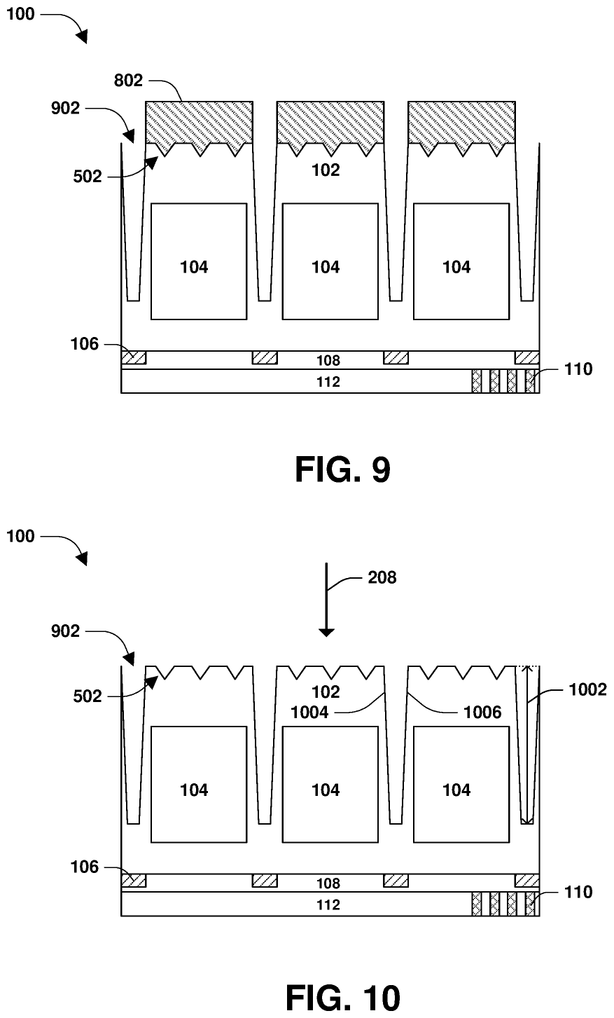

FIG. 9 illustrates use of the patterned photoresist 802 to form trenches 902 in the substrate 102, according to some embodiments. In some embodiments, an etching process is performed to form the trenches 902, where openings in the patterned photoresist 802 allow one or more etchants applied during the etching process to remove portions of the substrate 102 while the patterned photoresist 802 protects or shields portions of the substrate 102 that are covered by the patterned photoresist 802. The etching process is at least one of a dry etching process, a wet etching process, an anisotropic etching process, an isotropic etching process, or other suitable etching process. The etching process uses at least one of HF, diluted HF, a chlorine compound such as HCl₂, H₂S, or other suitable material. Other processes and techniques for forming the trenches 902 are within the scope of the present disclosure.

In some embodiments, the trenches 902 are between the components 104, such that the trenches 902 are laterally offset from the components 104. A trench 902 is between two adjacent components 104. In some embodiments, each of the trenches 902 is between two adjacent components 104. A trench 902 is laterally offset from a component 104 and a portion of the substrate 102 separates the trench 902 from the component 104. In some embodiments, a trench 902 is between two adjacent components 104, a first portion of the substrate 102 separates the trench 902 from a first component of the two adjacent components 104 and a second portion of the substrate 102 separates the trench 902 from a second component of the two adjacent components 104. Other structures and configurations of the trenches 902 are within the scope of the present disclosure.

FIG. 10 illustrates removal of the patterned photoresist 802, according to some embodiments. The patterned photoresist 802 is removed after the trenches 902 are formed. In some embodiments, the patterned photoresist 802 is removed by at least one of CMP, etching, or other suitable techniques. The etching process is at least one of a dry etching process, a wet etching process, an anisotropic etching process, an isotropic etching process, or other suitable etching process. The etching process uses at least one of HF, diluted HF, a chlorine compound such as HCl₂, H₂S or other suitable material. Other processes and techniques for removing the patterned photoresist 802 are within the scope of the present disclosure.

According to some embodiments, a portion of the substrate 102 has a first sidewall 1004 and a second sidewall 1006 defining a trench 902. According to some embodiments, at least one of the first sidewall 1004 is a tapered sidewall or the second sidewall 1006 is a tapered sidewall. At least one of the first sidewall 1004 has a first slope, such as a negative slope, or the second sidewall 1006 has a second slope, such as a positive slope. In some embodiments, the second slope is opposite in polarity relative to the first slope. In some embodiments, a cross-sectional area of a trench 902 decreases along the direction 208. A width of an uppermost portion of a trench 902 is greater than a width of a lowermost portion of the trench 902. Other structures and configurations of the trenches 902 are within the scope of the present disclosure.

In some embodiments, the etching process performed to form the trenches 902 is performed such that the substrate 102 has tapered sidewalls defining the trenches 902, such as the first sidewall 1004 and the second sidewall 1006. One or more etchants used to perform the etching process are designed or selected to form the tapered sidewalls in the substrate 102 defining the trenches 902. According to some embodiments, the substrate 102 having a specific crystallographic orientation, such as crystalline silicon with at least one of a <100>crystallographic orientation or a <110>crystallographic orientation, enables the etching process to form the tapered sidewalls in the substrate 102 defining the trenches 902. Other processes and techniques for forming the sidewalls defining the trenches 902 are within the scope of the present disclosure.

According to some embodiments, sidewalls defining a trench 902, such as the first sidewall 1004 and the second sidewall 1006, extend vertically, such as extend in a direction parallel to the direction 208 that radiation travels to enter the substrate 102 and be detected by the components 104. Other structures and configurations of the trenches 902 are within the scope of the present disclosure.

In some embodiments, a distance 1002 between a lowermost portion of a trench 902 and at least one of an uppermost portion of the trench 902 or the top surface of the substrate 102 is at least half of the thickness 206 of the substrate 102. Other values of the distance 1002 are within the scope of the present disclosure. The distance 1002 corresponds to a depth of a trench 902.

A lowermost portion of a trench 902 is lower than an uppermost portion of a component 104. According to some embodiments, the lowermost portion of the trench 902 is higher than a lowermost portion of the component 104. According to some embodiments, the lowermost portion of the trench 902 is lower than the lowermost portion of the component 104. According to some embodiments, the lowermost portion of the trench 902 is level with the lowermost portion of the component 104. Other structures and configurations of the trenches 902 and the components 104 are within the scope of the present disclosure.

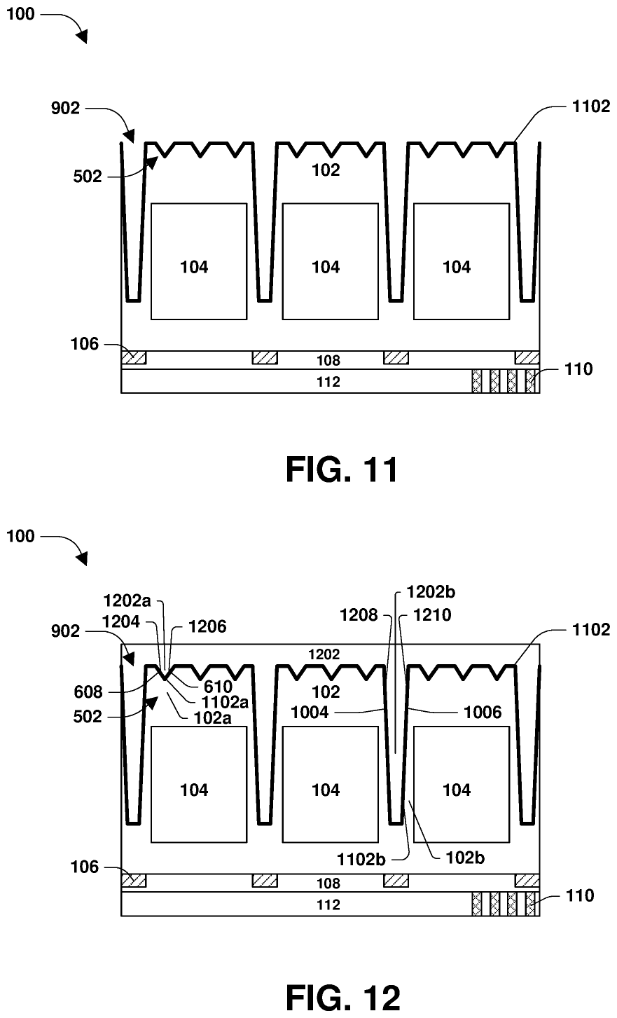

FIG. 11 illustrates a buffer layer 1102 formed over the substrate 102, according to some embodiments. In some embodiments, the buffer layer 1102 is in direct contact with the top surface of the substrate 102 and sidewalls defined in the substrate 102, such as sidewalls defining the recesses 502 and sidewalls defining the trenches 902. The buffer layer 1102 comprises at least one of a dielectric material, a high-k dielectric material, oxide such as a high-k oxide, an anti-reflection coating, SiO₂, HfSiON, HfSiOₓ, HfAlOₓ, HfO₂, ZrO₂, La₂O₃, Y₂O₃, or other suitable material. The buffer layer 1102 is formed by at least one of PVD, sputtering, CVD, LPCVD, ALCVD, UHVCVD, RPCVD, ALD, MBE, LPE, spin on, growth, or other suitable techniques. In some embodiments, the buffer layer 1102 is formed in the recesses 502, the trenches 902 and over the top surface of the substrate 102.

According to some embodiments, the buffer layer 1102 comprises a single layer. The single layer is configured to provide improved adhesion with a subsequently formed gap fill layer. According to some embodiments, the buffer layer 1102 comprises multiple layers. An outer layer of the multiple layers is configured to provide improved adhesion with the gap fill layer.

FIG. 12 illustrates the gap fill layer 1202 formed over at least one of the substrate 102 or the buffer layer 1102, according to some embodiments. According to some embodiments, the gap fill layer 1202 is in direct contact with the top surface of the substrate 102 and sidewalls defined in the substrate 102, such as sidewalls defining the recesses 502 and sidewalls defining the trenches 902. Where the semiconductor arrangement 100 comprises the buffer layer 1102 over the substrate 102, the gap fill layer 1202 is in direct contact with at least one of a top surface of the buffer layer 1102 or sidewalls of the buffer layer 1102. The gap fill layer 1202 comprises at least one of a metal material, a dielectric material, a high-k dielectric material, SiO₂, HfSiON, HfSiOₓ, HfAlOₓ, HfO₂, ZrO₂, La₂O₃, Y₂O₃ or other suitable material. The gap fill layer 1202 is formed by at least one of PVD, sputtering, CVD, LPCVD, ALCVD, UHVCVD, RPCVD, ALD, MBE, LPE, spin on, growth, or other suitable techniques. The gap fill layer 1202 is formed at least one of in the recesses 502, in the trenches 902, or over the top surface of the substrate 102. In some embodiments, the gap fill layer 1202 overlies the top surface of the substrate 102 and sidewalls defined in the substrate 102, such as sidewalls defining the recesses 502 and sidewalls defining the trenches 902. Where the semiconductor arrangement 100 comprises the buffer layer 1102 over the substrate 102, the buffer layer 1102 separates the gap fill layer 1202 from the substrate 102. Other structures and configurations of the gap fill layer 1202 are within the scope of the present disclosure.

A first portion 1202a of the gap fill layer 1202 is in a recess 502. The first portion 1202a of the gap fill layer 1202 has a third tapered sidewall 1204 with which the first tapered sidewall 608 of the substrate 102 aligns. Where the semiconductor arrangement 100 comprises the buffer layer 1102 over the substrate 102, a portion of the buffer layer 1102 separates the third tapered sidewall 1204 of the first portion 1202a of the gap fill layer 1202 from the first tapered sidewall 608 of the substrate 102. In some embodiments, the first portion 1202a of the gap fill layer 1202 has a fourth tapered sidewall 1206 with which the second tapered sidewall 610 of the substrate 102 aligns. Where the semiconductor arrangement 100 comprises the buffer layer 1102 over the substrate 102, a portion of the buffer layer 1102 separates the fourth tapered sidewall 1206 of the first portion 1202a of the gap fill layer 1202 from the second tapered sidewall 610 of the substrate 102. The first portion 1202a of the gap fill layer 1202 overlies a component 104. In some embodiments, at least one of a portion 1102a of the buffer layer 1102 or a portion 102a of the substrate 102 separates the first portion 1202a of the gap fill layer 1202 from the component 104. Other structures and configurations of the gap fill layer 1202 and the substrate 102 are within the scope of the present disclosure.

In some embodiments, the first portion 1202a of the gap fill layer 1202 in the recess 502 defined in the substrate 102 is a HA structure, such as due, at least in part, to at least one of the third tapered sidewall 1204 of the first portion 1202a of the gap fill layer 1202, the first tapered sidewall 608 of the substrate 102, the fourth tapered sidewall 1206 of the first portion 1202a of the gap fill layer 1202, or the second tapered sidewall 610 of the substrate 102. The HA structure directs more radiation to the component 104 underlying the first portion 1202a of the gap fill layer 1202 as compared to a portion of the gap fill layer that does not have one or more tapered sidewalls and an underlying substrate with one more corresponding tapered sidewalls. One or more additional portions of the gap fill layer in recesses 502 in the substrate 102 are similarly constructed HA structures that overlie a component 104. Other structures and configurations of the HA structures are within the scope of the present disclosure.

A second portion 1202b of the gap fill layer 1202 is in a trench 902. The second portion 1202b of the gap fill layer 1202 has a third sidewall 1208 with which the first sidewall 1004 of the substrate 102 aligns. According to some embodiments, the third sidewall 1208 of the second portion 1202b of the gap fill layer 1202 and the first sidewall 1004 of the substrate 102 are tapered. According to some embodiments, the third sidewall 1208 of the second portion 1202b of the gap fill layer 1202 and the first sidewall 1004 of the substrate 102 extend vertically. Where the semiconductor arrangement 100 comprises the buffer layer 1102 over the substrate 102, a portion of the buffer layer 1102 separates the third sidewall 1208 of the second portion 1202b of the gap fill layer 1202 from the first sidewall 1004 of the substrate 102. The second portion 1202b of the gap fill layer 1202 has a fourth sidewall 1210 with which the second sidewall 1006 of the substrate 102 aligns. According to some embodiments, the fourth sidewall 1210 of the second portion 1202b of the gap fill layer 1202 and the second sidewall 1006 of the substrate 102 are tapered. According to some embodiments, the fourth sidewall 1210 of the second portion 1202b of the gap fill layer 1202 and the second sidewall 1006 of the substrate 102 extend vertically. Where the semiconductor arrangement 100 comprises the buffer layer 1102 over the substrate 102, a portion of the buffer layer 1102 separates the fourth sidewall 1210 of the second portion 1202b of the gap fill layer 1202 from the second sidewall 1006 of the substrate 102. Other structures and configurations of the second portion 1202b of the gap fill layer 1202 are within the scope of the present disclosure.

In some embodiments, the second portion 1202b of the gap fill layer 1202 is laterally offset from a component 104 and at least one of a portion 1102b of the buffer layer 1102 or a portion 102b of the substrate 102 separates the second portion 1202b of the gap fill layer 1202 from the component 104. The second portion 1202b of the gap fill layer 1202 is between two adjacent components 104. In some embodiments, a first portion of the substrate 102 separates the second portion 1202b of the gap fill layer 1202 from a first component of the two adjacent components 104, and a second portion of the substrate 102 separates the second portion 1202b of the gap fill layer 1202 from a second component of the two adjacent components 104. Other structures and configurations of the second portion 1202b of the gap fill layer 1202 are within the scope of the present disclosure.

In some embodiments, the second portion 1202b of the gap fill layer 1202 in the trench 902 defined in the substrate 102 is a DTI structure in the substrate 102. The DTI structure is a BDTI structure or a different type of DTI structure. In some embodiments, the DTI structure is laterally offset from a component 104 and a portion of the substrate 102 separates the DTI structure from the component 104. In some embodiments, the DTI structure is between two adjacent components 104, a first portion of the substrate 102 separates the DTI structure from a first component of the two adjacent components 104, and a second portion of the substrate 102 separates the DTI structure from a second component of the two adjacent components 104. Other structures and configurations of the DTI structure are within the scope of the present disclosure.

In some embodiments, DTI structures are formed by forming the gap fill layer 1202 in the trenches 902. A DTI structure corresponds to material, such as at least one of a portion of the buffer layer 1102 or a portion of the gap fill layer 1202, in a trench 902. A DTI structure corresponds to material, such as at least one of a portion of the buffer layer 1102 or a portion of the gap fill layer 1202, that fills a trench 902. A DTI structure is between two adjacent components 104, such that the DTI structure is laterally offset from a first component of the two adjacent components 104 and is laterally offset from a second component of the two adjacent components 104. In some embodiments, DTI structures are respectively disposed between two adjacent components 104. Other structures and configurations of the DTI structures are within the scope of the present disclosure.

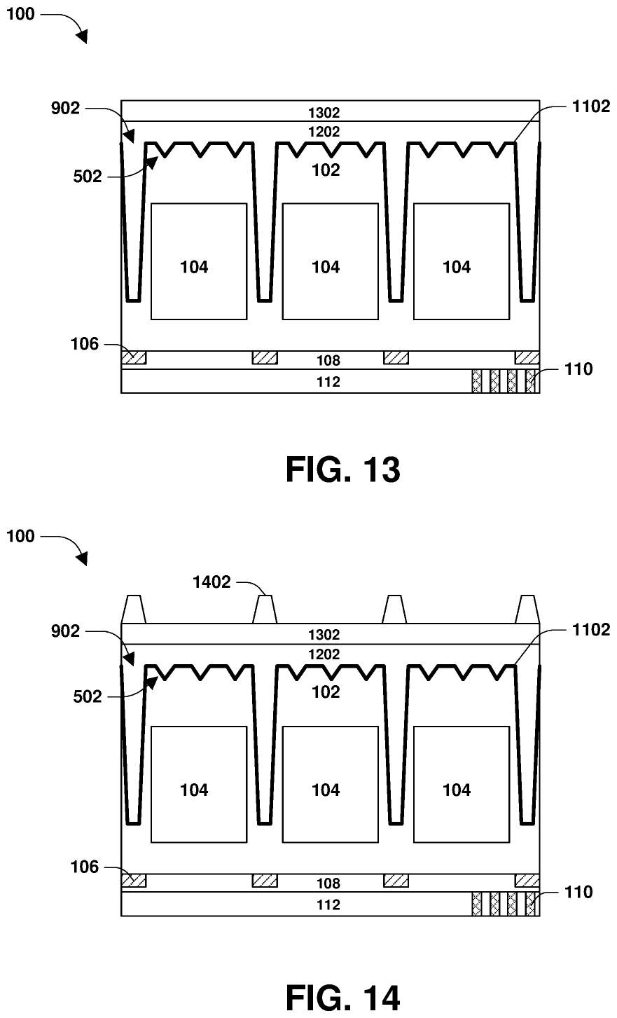

FIG. 13 illustrates a third dielectric layer 1302 formed over the gap fill layer 1202, according to some embodiments. In some embodiments, the third dielectric layer 1302 is in direct contact with a top surface of the gap fill layer 1202. The third dielectric layer 1302 comprises at least one of oxide or other suitable material. In some embodiments, the third dielectric layer 1302 comprises a material that is substantially optically transparent to wavelengths of radiation intended to be received by the components 104, such as NIR wavelengths. Other materials of the third dielectric layer 1302 and other wavelengths of radiation to which material of the third dielectric layer 1302 is substantially optically transparent are within the scope of the present disclosure. The third dielectric layer 1302 is formed by at least one of PVD, sputtering, CVD, LPCVD, ALCVD, UHVCVD, RPCVD, ALD, MBE, LPE, spin on, growth, or other suitable techniques.

FIG. 14 illustrates grid structures 1402 formed over the third dielectric layer 1302, according to some embodiments. In some embodiments, the grid structures 1402 are in direct contact with a top surface of the third dielectric layer 1302. The grid structures 1402 are between the components 104, such that the grid structures 1402 at least one of do not overlie or are laterally offset from the components 104. A grid structure 1402 is disposed between two adjacent components 104, such that the grid structure 1402 overlies a portion of the substrate 102 between a first component 104 and a second component 104. In some embodiments, at least some of the grid structures 1402 have at least one tapered sidewall. The grid structures 1402 comprise at least one of a dielectric material, an oxide, a metal material, or other suitable material. In some embodiments, the grid structures 1402 are formed by forming one or more grid structure layers over the third dielectric layer 1302 and patterning the one or more grid structure layers to form the grid structures 1402. The one or more grid structure layers are formed by at least one of PVD, sputtering, CVD, LPCVD, ALCVD, UHVCVD, RPCVD, ALD, MBE, LPE, spin on, growth, or other suitable techniques. The one or more grid structure layers are patterned to form the grid structures 1402 by at least one of using a photoresist, a hard mask layer, an etching process, or other suitable techniques. In some embodiments, two adjacent grid structures 1402 provide an optical path through which radiation is guided by the two adjacent grid structures 1402 to a component 104 between the two adjacent grid structures 1402. Other structures and configurations of the grid structures 1402 are within the scope of the present disclosure.

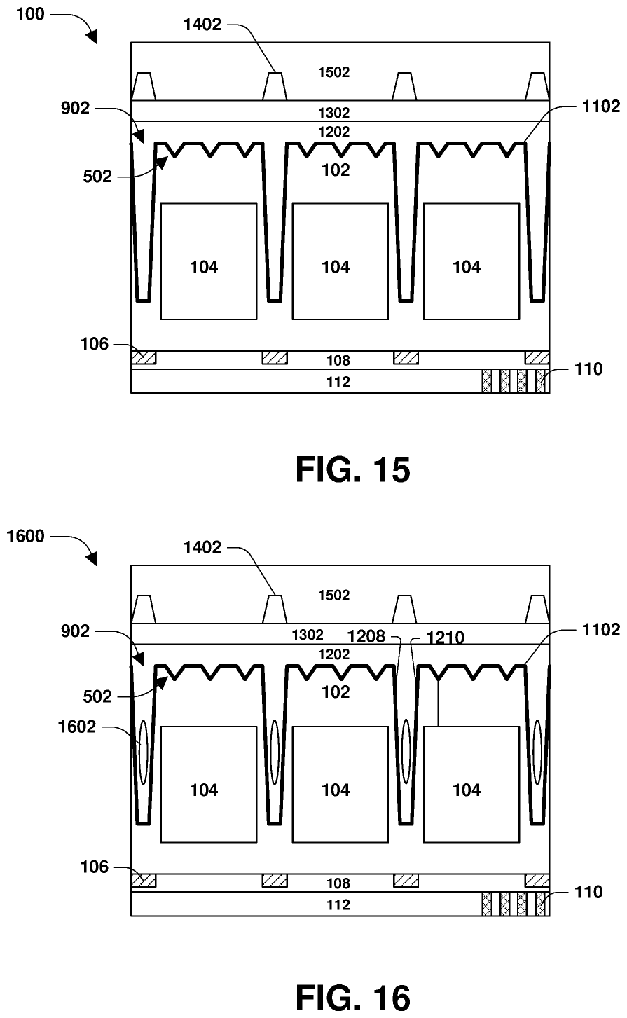

FIG. 15 illustrates a passivation layer 1502 formed over at least one of the grid structures 1402 or the third dielectric layer 1302, according to some embodiments. In some embodiments, the passivation layer 1502 is in direct contact with at least one of the top surface of the third dielectric layer 1302, sidewalls of the grid structures 1402, or top surfaces of the grid structures 1402. In some embodiments, a portion of the passivation layer 1502 overlies a grid structure 1402. The passivation layer 1502 comprises oxide or other suitable material. In some embodiments, the passivation layer 1502 comprises a material that is substantially optically transparent to wavelengths of radiation intended to be received by the components 104, such as NIR wavelengths. Other materials of the passivation layer 1502 and other wavelengths of radiation to which material of the passivation layer 1502 is substantially optically transparent are within the scope of the present disclosure. The passivation layer 1502 is formed by at least one of PVD, sputtering, CVD, LPCVD, ALCVD, UHVCVD, RPCVD, ALD, MBE, LPE, spin on, growth, or other suitable techniques.

FIG. 16 illustrates a cross-sectional view of a semiconductor arrangement 1600, according to some embodiments. The semiconductor arrangement 1600 comprises at least some elements, structures, layers, features, etc. of the semiconductor arrangement 100. In some embodiments, the semiconductor arrangement 1600 comprises one or more gaps 1602, such as gaps comprising air, between the components 104. A gap 1602 is defined in at least one of a portion of the gap fill layer 1202 in a trench 902 or a DTI structure. In some embodiments, a gap 1602 is between two sidewalls of the portion of the gap fill layer 1202. A gap 1602 is between the third sidewall 1208 of the portion of the gap fill layer and the fourth sidewall 1210 of the portion of the gap fill layer. Other structures and configurations of the one or more gaps 1602 are within the scope of the present disclosure.

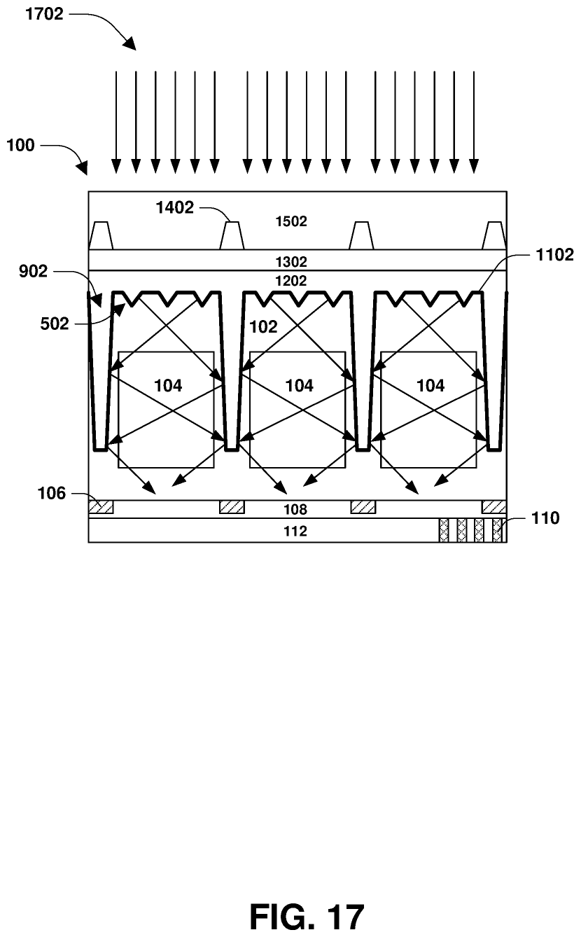

FIG. 17 illustrates a cross-sectional view of the semiconductor arrangement 100, according to some embodiments. FIG. 17 illustrates radiation 1702 projected towards the semiconductor arrangement 100, according to some embodiments. At least some of the radiation 1702 passes through at least one of the passivation layer 1502, the third dielectric layer 1302, the gap fill layer 1202, or some of the substrate 102, and is at least one of sensed, detected, or converted to electrons by the components 104. HA structures, such as portions of the gap fill layer 1202 in the recesses 502 overlying the components 104, provide for an increase in an amount of radiation, of the radiation 1702, that is at least one of sensed, detected, or converted by the components 104, in comparison with other sensors that do not implement the HA structures. In some embodiments, the increase in the amount of radiation is due to HA structures providing improved optical paths for guiding radiation to the components 104. In some embodiments, the improved optical paths are achieved by HA structures at least one of having triangular shapes or having tapered sidewalls aligned with tapered sidewalls defined in the substrate 102. Implementing the HA structures at least one of having triangular shapes or having tapered sidewalls aligned with tapered sidewalls defined in the substrate 102 mitigates reflection or deflection by the substrate 102 of radiation, projected towards a component 104, away from the component 104. In some embodiments, the radiation 1702 comprises NIR radiation, such as radiation with a wavelength between about 700 nanometers and about 2500 nanometers. In some embodiments, the radiation 1702 comprises about 940 nanometer wavelength radiation. Other wavelengths of radiation at least one of sensed, detected, or converted by the components 104 are within the scope of the present disclosure.

In some embodiments, DTI structures, such as portions of the gap fill layer 1202 in the trenches 902 between the components 104, at least one of prevent or mitigate crosstalk between components 104. The DTI structures at least one of prevent or mitigate radiation from traveling from a first component 104 to a second component 104, or simply away from the first component 104 when there is no second component adjacent the first component 104. Radiation traveling away the first component 104 is reflected by a DTI structure back towards the first component 104. In some embodiments, much more of the radiation is detected by or registers with the first component 104 due to the radiation being directed back towards the first component 104.

In some embodiments, at least one of the HA structures or the DTI structures provide for an increase in at least one of a MTF or a spatial frequency response of the sensor in comparison with other sensors that do not implement at least one of the HA structures or the DTI structures. The increase in at least one of the MTF or the spatial frequency response is due, at least in part, to radiation being channeled, directed, reflected, etc. toward a component, such as a photodiode. In some embodiments, at least one of the HA structures or the DTI structures provide for an improvement in resolution in comparison with other sensors that do not implement at least one of the HA structures or the DTI structures. The improvement in resolution is due, at least in part, to radiation being channeled, directed, reflected, etc. toward a component, such as a photodiode. In some embodiments, at least one of the HA structures or the DTI structures provide for an improved QE of a sensor implemented via the semiconductor arrangement 100, such as about a 14% increase in QE, in comparison with other sensors that do not implement at least one of the HA structures or the DTI structures. Other increases in QE are within the scope of the present disclosure. Accordingly, at least one of the HA structures or the DTI structures provide for an increase in radiation, such as NIR radiation, being sensed, detected, converted to electrons, etc. Other types of radiation having other wavelengths are within the scope of the present disclosure.

In some embodiments, the sensor is configured to determine distances between the sensor and surrounding objects. At least one of the HA structures or the DTI structures provide for more accurate determinations of distances between the sensor and the surrounding objects in comparison with other sensors that do not implement at least one of the HA structures or the DTI structures.

In some embodiments, the sensor is configured to generate images. At least one of the HA structures or the DTI structures provide for at least one of more accurate generation of the images or generation of the images with improved resolutions in comparison with other sensors that do not implement at least one of the HA structures or the DTI structures.

In some embodiments, the sensor is configured to generate depth maps indicative of distances between the sensor and surrounding objects. At least one of the HA structures or the DTI structures provide for at least one of more accurate generation of the depth maps or generation of the depth maps with improved resolutions in comparison with other sensors that do not implement at least one of the HA structures or the DTI structures.

In some embodiments, the sensor is used by a vehicle configured to navigate based upon distances between the sensor and surrounding objects. At least one of the HA structures or the DTI structures provide for at least one of more accurate navigation of the vehicle or a reduced probability that the vehicle contacts an object in comparison with other sensors that do not implement at least one of the HA structures or the DTI structures. The vehicle is at least one of an automated guided vehicle (AGV) or a different type of vehicle. According to some embodiments, the vehicle operates in an environment having NIR radiation. Other structures and configurations of the sensor are within the scope of the present disclosure.

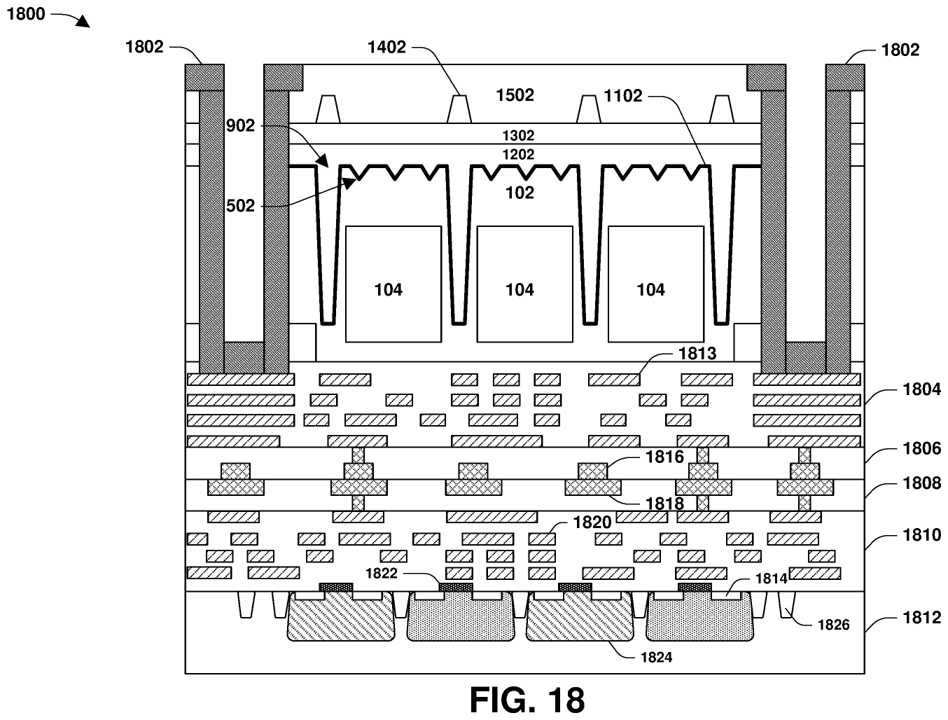

FIG. 18 illustrates a cross-sectional view of a semiconductor arrangement 1800, according to some embodiments. The semiconductor arrangement 1800 comprises at least some elements, structures, layers, features, etc. of at least one of the semiconductor arrangement 100 or the semiconductor arrangement 1600. In some embodiments, the semiconductor arrangement 1800 comprises connection structures 1802. The connection structures 1802 comprise a conductive material, such as a metal material or other suitable material. According to some embodiments, the semiconductor arrangement 1800 is connected to external circuitry via the connection structures 1802. According to some embodiments, the connection structures 1802 comprise at least one of metal pads or metal terminals. Other structures and configurations of the connection structures 1802 are within the scope of the present disclosure.

In some embodiments, the semiconductor arrangement 1800 comprises a first interconnect layer 1804. The first interconnect layer 1804 is under at least one of the substrate 102 or the connection structures 1802. The first interconnect layer 1804 comprises patterned dielectric layers and conductive layers that provide interconnections, such as wiring, between at least one of various doped features, circuitry, input/output, etc. of the semiconductor arrangement 1800. In some embodiments, the first interconnect layer 1804 comprises an interlayer dielectric and multilayer interconnect structures, such as at least one of contacts, vias, metal lines, or a different type of structure. Other structures and configurations of the first interconnect layer 1804 are within the scope of the present disclosure. For purposes of illustration, the first interconnect layer 1804 comprises conductive lines 1813, where the positioning and configuration of such conductive lines might vary depending upon design needs.

In some embodiments, at least one of the second dielectric layer 108 or the first dielectric layer 112 (not shown in FIG. 18) are between the first interconnect layer 1804 and the substrate 102. In some embodiments, the first interconnect layer 1804 comprises at least one of the second dielectric layer 108 or the first dielectric layer 112 (not shown in FIG. 18). In some embodiments, at least one of the second dielectric layer 108 or the first dielectric layer 112 are not between the first interconnect layer 1804 and the substrate 102.

In some embodiments, the semiconductor arrangement 1800 comprises a first wafer and a second wafer. The first wafer corresponds to a sensor wafer and the second wafer corresponds to a logic wafer, such as an application-specific integrated circuit (ASIC) logic wafer. Other structures and configurations of the first wafer and the second wafer are within the scope of the present disclosure. The first wafer comprises at least one of the first interconnect layer 1804, the connection structures 1802, a first connection layer 1806, or at least some elements, structures, layers, features, etc. of at least one of the semiconductor arrangement 100 or the semiconductor arrangement 1600. The second wafer comprises at least one of a second connection layer 1808, a second interconnect layer 1810, or a second substrate 1812.

According to some embodiments, the first connection layer 1806 of the first wafer is connected to the second connection layer 1808 of the second wafer, such as by an adhesive. The first connection layer 1806 comprises first conductive structures 1816, such as conductive structures that provide interconnections, such as wiring, between at least one of various doped features, circuitry, input/output, etc. of the semiconductor arrangement 1800. Other structures and configurations of the first connection layer 1806 and the first conductive structures 1816 are within the scope of the present disclosure. The second connection layer 1808 comprises second conductive structures 1818, such as conductive structures that provide interconnections, such as wiring, between at least one of various doped features, circuitry, input/output, etc. of the semiconductor arrangement 1800. Other structures and configurations of the second connection layer 1808 and the second conductive structures 1818 are within the scope of the present disclosure. In some embodiments, at least some of the first conductive structures 1816 are connected to at least some of the second conductive structures 1818.

The second interconnect layer 1810 is under the second connection layer 1808. The second interconnect layer 1810 comprises patterned dielectric layers and conductive layers that provide interconnections, such as wiring, between at least one of various doped features, circuitry, input/output, etc. of the semiconductor arrangement 1800. In some embodiments, the second interconnect layer 1810 comprises an interlayer dielectric and multilayer interconnect structures, such as at least one of contacts, vias, metal lines, or a different type of structure. Other structures and configurations of the second interconnect layer 1810 are within the scope of the present disclosure. For purposes of illustration, the second interconnect layer 1810 comprises conductive lines 1820, where the positioning and configuration of such conductive lines might vary depending upon design needs.

In some embodiments, the second substrate 1812 is under the second interconnect layer 1810. The second substrate 1812 comprises at least one of an epitaxial layer, a SOI structure, a wafer, or a die formed from a wafer. The second substrate 1812 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GalnAs, GaInP, GalnAsP or other suitable material. In some embodiments, the second substrate 1812 comprises at least one doped region. Other structures and configurations of the second substrate 1812 are within the scope of the present disclosure. At least one of one or more shallow trench isolation (STI) regions 1826 or one or more doped well regions 1824 are disposed in the second substrate 1812. In some embodiments, at least one of the doped well regions 1824 comprise source/drain regions 1814, or rather source/drain regions are formed in the doped well regions 1824. In some embodiments, polysilicon structures 1822 overlie at least one of the one or more doped well regions 1824. In some embodiments, the second substrate 1812 comprises one or more transistors where the polysilicon structures 1822 serve as gates for the transistors and the source/drain regions 1814 serve as source/drain regions for the transistors. Other structures and configurations of the second substrate 1812, the one or more STI regions 1826, the doped well regions 1824, and the source/drain regions 1814 are within the scope of the present disclosure.

According to some embodiments, at least one of the one or more layers, features, structures, elements, etc. disclosed herein are in direct contact with another of the one or more layers, features, structures, elements, etc. disclosed herein. According to some embodiments, at least one of the one or more layers, features, structures, elements, etc. disclosed herein are not in direct contact with another of the one or more layers, features, structures, elements, etc. disclosed herein, such as where one or more intervening, separating, etc. layers, features, structures, elements, etc. exist.

In some embodiments, a semiconductor arrangement is provided. The semiconductor arrangement includes a first component in a substrate. The semiconductor arrangement includes a gap fill layer. A first portion of the gap fill layer overlies the first component. The first portion of the gap fill layer has a tapered sidewall. A first portion of the substrate separates the first portion of the gap fill layer from the first component.

In some embodiments, a semiconductor arrangement is provided. The semiconductor arrangement includes a first component in a substrate. The semiconductor arrangement includes a gap fill layer. A first portion of the gap fill layer overlies the first component. A second portion of the gap fill layer is laterally offset from the first component. A first portion of the substrate separates the second portion of the gap fill layer from the first component.

In some embodiments, a method for forming a semiconductor arrangement is provided. The method includes forming a first recess in a substrate, wherein the first recess overlies a first component in the substrate. The method includes forming a first trench in the substrate, wherein the first trench is between the first component and a second component in the substrate. The method includes forming a gap fill layer in the first recess and the first trench such that a first portion of the gap fill layer overlies the first component and a second portion of the gap fill layer is between the first component and the second component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method for forming a semiconductor arrangement, comprising:
forming a first recess in a substrate, wherein the first recess overlies a first component in the substrate;
forming a first trench in the substrate, wherein the first trench is between the first component and a second component in the substrate; and
forming a gap fill layer in the first recess and the first trench such that a first portion of the gap fill layer overlies the first component and a second portion of the gap fill layer is between the first component and the second component.

2. The method of claim 1, wherein forming the first recess comprises forming the first recess to have a tapered sidewall.

3. The method of claim 2, comprising:
forming a second recess in the substrate, wherein the second recess overlies the first component and has a tapered sidewall; and
forming the gap fill layer in the second recess such that a third portion of the gap fill material overlies the first component.

4. The method of claim 1, wherein forming the first trench comprises forming the first trench to have a tapered sidewall.

5. The method of claim 1, wherein forming the first recess comprises:
forming a hard mask layer over the substrate;
patterning the hard mask layer to generate a patterned hard mask layer; and
etching the substrate using the patterned hard mask layer to form the first recess.

6. The method of claim 1, comprising:
forming one or more structures on a first surface of the substrate prior to forming the first recess, wherein:
forming the first recess comprises forming the first recess through a second surface of the substrate, and
the second surface is a backside surface of the substrate.

7. The method of claim 1, wherein forming the first recess comprises:
etching the substrate to define a first partial recess having a first cross-sectional profile; and
etching the substrate to modify the first partial recess to form the first recess having a second cross-sectional profile different than the first cross-sectional profile.

8. The method of claim 1, comprising, before forming the first trench:
forming a photoresist in the first recess; and
patterning the photoresist to expose a portion of the substrate, wherein the photoresist remains in the first recess after patterning the photoresist.

9. The method of claim 1, comprising:
forming a buffer layer in the first recess and the first trench prior to forming the gap fill layer, wherein the gap fill layer is separated from the substrate by the buffer layer.

10. The method of claim 1, wherein forming the gap fill layer comprises forming the gap fill layer to define an airgap within the gap fill layer between the first component and the second component.

11. The method of claim 1, wherein:
the first recess extends from a surface of the substrate a first depth into the substrate,
the first trench extends from the surface of the substrate a second depth into the substrate, and
the second depth is greater than the first depth.

12. A method for forming a semiconductor arrangement, comprising:
etching a surface of a substrate to define a recess over a first photodiode disposed within the substrate;
forming a photoresist in the recess, wherein a portion of the surface of the substrate is exposed after forming the photoresist; and
etching the portion of the surface to define a trench, wherein:
the trench extends from the surface to a first depth in the substrate,
the first photodiode is spaced apart from the surface of the substrate by a first distance, and
the first distance is less than the first depth.

13. The method of claim 12, comprising:
forming a gap fill layer in the recess and in the trench.

14. The method of claim 13, comprising forming a grid structure over the gap fill layer.

15. The method of claim 14, wherein the grid structure overlies the trench.

16. The method of claim 13, comprising:
forming a buffer layer in the recess and in the trench prior to forming the gap fill layer.

17. The method of claim 12, wherein the recess is defined by a tapered sidewall of the substrate.

18. A method for forming a semiconductor arrangement, comprising:
etching a substrate to define a recess overlying a first photodiode disposed within the substrate, wherein the recess is defined by a tapered sidewall of the substrate;
forming a gap fill layer in the recess; and
forming a grid structure over the gap fill layer.

19. The method of claim 18, wherein:
a second photodiode is disposed within the substrate, and
forming the grid structure comprises forming the grid structure to overlie a portion of the substrate between the first photodiode and the second photodiode.

20. The method of claim 18, wherein:
a second photodiode is disposed within the substrate, and
forming the gap fill layer comprises forming the gap fill layer such that a portion of the gap fill layer is laterally between the first photodiode and the second photodiode.
